(19) United States
(12) Patent Application Publication
(10) Pub. No.: US 2021/0307206 A1
(43) Pub. Date: Sep. 30, 2021

(54) VAPOR CHAMBER STRUCTURE

(71) Applicant: TAIWAN MICROLOOPS CORP., New Taipei City (TW)

(72) Inventor: Chun-Hung LIN, New Taipei City (TW)

(21) Appl. No.: 16/828,924

(22) Filed: Mar. 24, 2020

(51) Int. Cl. H05K 7/20

(52) U.S. Cl. CPC H05K 7/20481; H05K 7/20336

(57) ABSTRACT

A vapor chamber structure includes a thin-sheet housing with a hollow interior and a capillary layer installed in the thin-sheet housing. The hollow interior of the thin-sheet housing is formed by an etching method, and plural first support portions are formed in the thin-sheet housing, and a first material layer and a second material layer are coated onto two inner walls of the thin-sheet housing respectively, and the capillary layer is attached onto the first material layer closely. With the first and second material layers coated onto the interior of the thin-sheet housing, the thin-sheet housing has a high structural rigidity.

### BACKGROUND OF THE INVENTION

### 1. Technical Field

The technical field relates to a vacuum heat transfer element, and more particularly to an improved vapor chamber structure.

### 2. Description of Related Art

Since the computing power of various electronic products keeps improving, and thermal dissipation becomes an issue, therefore vapor chambers (also known as flat heat pipes) are indispensable heat dissipating components.

However, electronic products tend to be designed with a light and thin design, so that the vapor chamber (or flat heat pipe) has to be thin. Therefore, the capillary effect of a capillary tissue in the vapor chamber will be affected by the requirement for the thin design. If a thin material used for the capillary tissue cannot be found, it will be difficult to meet the requirement for the thin design and the vapor chamber (or flat heat pipe) will not be suitable for the thin design of the electronic products.

In view of the aforementioned drawback of the conventional vapor chamber, the discloser of this disclosure based on years of experience in the related industry to conduct extensive research and experiment, and finally provided a feasible solution to overcome the drawbacks of the prior art.

### SUMMARY OF THE INVENTION

Therefore, it is a primary object of this disclosure to provide a vapor chamber structure with a material layer coated onto an inner surface of a housing of the vapor chamber and provided for improving the structural rigidity of the housing, so that such structure can be applicable for a thin vapor chamber.

To achieve the aforementioned and other objectives, this disclosure provides a vapor chamber structure, comprising: a thin-sheet housing, with an interior in a substantially hollow form; and a capillary layer, installed in the thin-sheet housing; wherein, the thin-sheet housing has the hollow form formed therein by an etching method, and a plurality of first support portions is formed therein, and a first material layer and a second material layer are coated onto two inner walls of the thin-sheet housing respectively, and the capillary layer is attached onto the first material layer closely.

### BRIEF DESCRIPTION OF THE DRAWINGS

FIG. 1 is an exploded view of a vapor chamber structure in accordance with a first embodiment of this disclosure;

FIG. 2 is a cross-sectional view of a vapor chamber structure in accordance with the first embodiment of this disclosure;

FIG. 3 shows a cross-sectional view and a partial blowup view of a vapor chamber structure in accordance with the first embodiment of this disclosure; and

FIG. 4 shows a cross-sectional view and a partial blowup view of a vapor chamber structure in accordance with a second embodiment of this disclosure.

### DESCRIPTION OF THE PREFERRED EMBODIMENTS

The technical contents of this disclosure will become apparent with the detailed description of preferred embodiments accompanied with the illustration of related drawings as follows. It is intended that the embodiments and drawings disclosed herein are to be considered illustrative rather than restrictive.

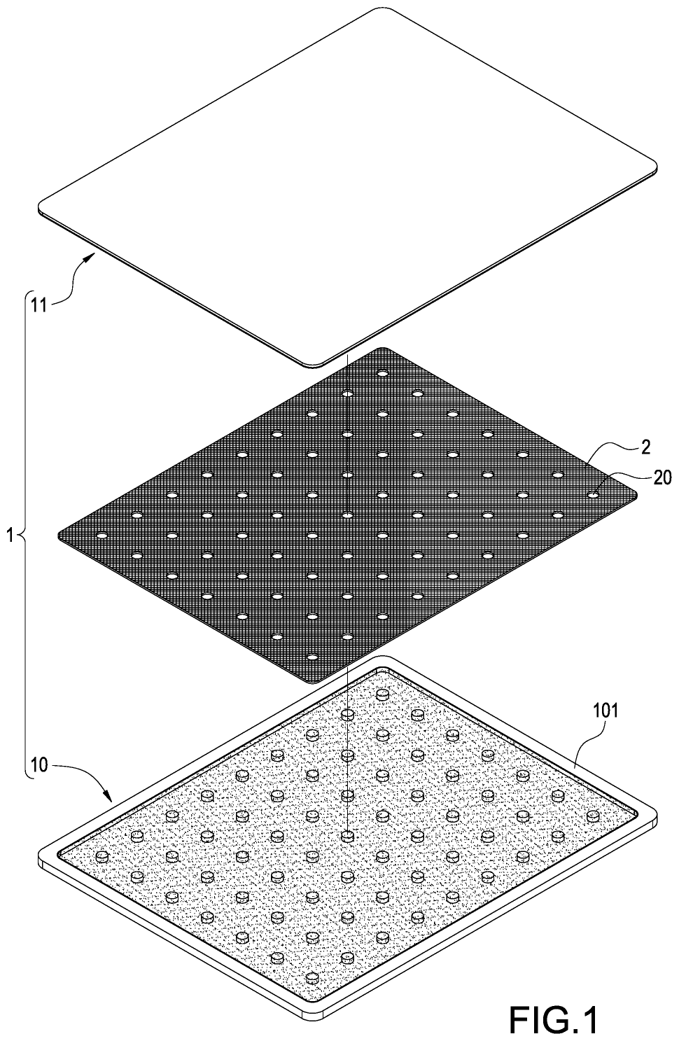

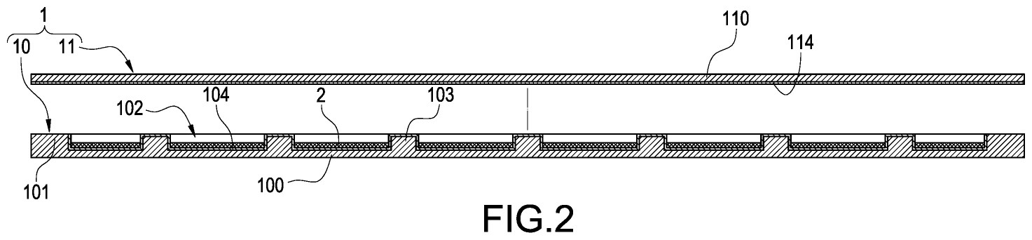

With reference to FIGS. 1 and 2 for the exploded view and the cross-sectional view of a vapor chamber structure in accordance with the first embodiment of this disclosure respectively, the vapor chamber structure comprises a thin-sheet housing 1, and a capillary layer 2 installed in the thin-sheet housing 1.

The hollow interior of the thin-sheet housing 1 is formed by covering a first plate 10 and a second plate 11 with each other. In the first embodiment of this disclosure, the first plate 10 has a first thin-sheet portion 100, and a first sealing edge 101 formed continuously around the periphery of the first thin-sheet portion 100, and a first recessed space 102 is formed and enclosed by the first thin-sheet portion 100 and the first sealing edge 101, and then the second plate 11 is covered onto the first sealing edge 101 to seal the first recessed space 102, so as to form the thin-sheet housing 1. In addition, the first recessed space 102 is formed by recessing a surface of the first thin-sheet portion 100 inwardly by an etching method, and the non-etched portion of the first recessed space 102 is reserved for forming a plurality of first support portions 103 provided the second plate 11 to seal the first recessed space 102 and stacked onto the first plate 10, so that the first support portions 103 can abut against the inner surface of the second plate 11 to serve as a support structure.

The capillary layer 2 is disposed in the thin-sheet housing 1. In the first embodiment of this disclosure, the capillary layer 2 is disposed in the first recessed space 102, and the capillary layer 2 is formed by braiding a plurality of metal filaments, and a plurality of positioning holes 20 configured to be corresponsive to the first support portions 103 may be formed on the capillary layer 2 for fixing the capillary layer 2 into the first recessed space 102 of the first plate 10.

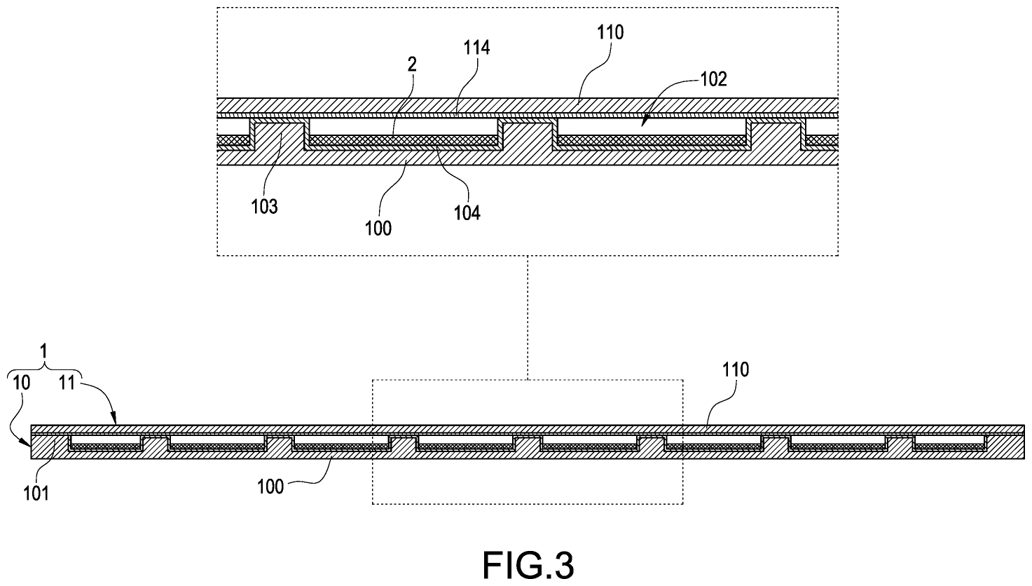

With reference to FIG. 3 as well, this disclosure mainly has a first material layer 104 and a second material layer 114 coated onto two inner walls of the thin-sheet housing 1 respectively, wherein the thin-sheet housing 1 is made of a material such as steel, titanium or aluminum to provide a good structural rigidity. Specifically, the first material layer 104 is coated onto the etched portion of the inner surface of the first thin-sheet portion 100, and also coated onto each of the first support portions 103, so that when the capillary layer 3 is positioned by each respective first support portion 103 in the first recessed space 102, the capillary layer 3 is further attached onto the first material layer 104 closely. In addition, the first material layer 104 and the second material layer 114 may be formed by coating, and the material of the coating can be titanium.

By the aforementioned structural assembly, the improved vapor chamber structure of this disclosure is achieved.

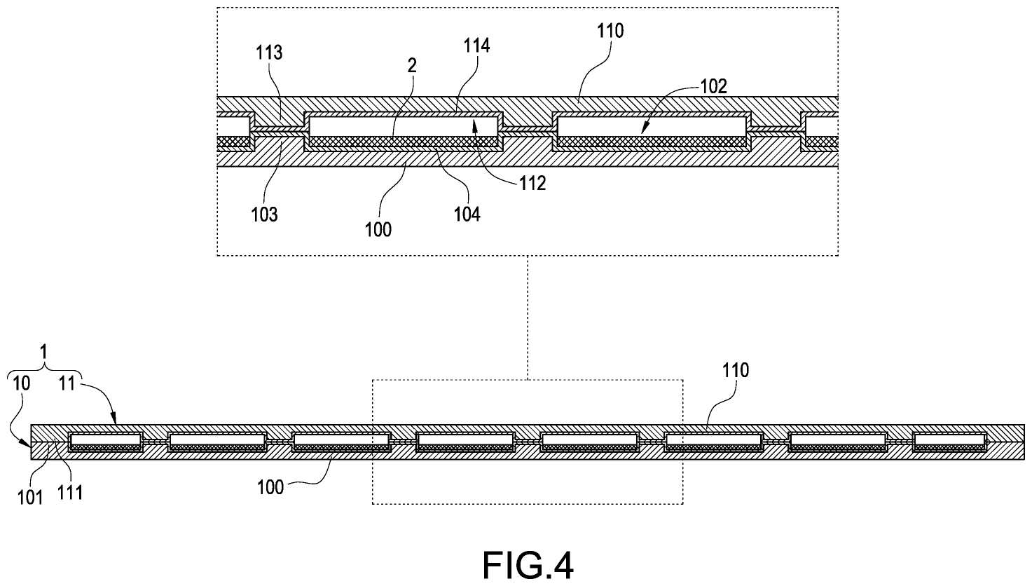

With reference to FIG. 4 for the second embodiment of this disclosure, the second plate 11 of the thin-sheet housing 1 also has a second thin-sheet portion 110, and a second sealing edge 111 continuously formed around the periphery of the second thin-sheet portion 110, and a second recessed space 112 is formed and enclosed by the second thin-sheet portion 110 and the second sealing edge 111. When the second plate 11 and the first plate 10 are covered with each other, the first and second sealing edges 101, 111 of the first and second plates 10, 11 are coupled closely to seal the first and second recessed spaces 102, 112 respectively, so as to provide other feasible embodiment of the thin-sheet housing 1. In addition, the second recessed space 112 may be formed inwardly on a surface of the second plate 11 by etching, and the non-etched portion of the second recessed space 112 is reserved for forming a plurality of second support portions 113, so that when the second plate 11 and the first plate 10 are covered with each other, the first support portions 103 and the second support portions 113 abut against each other to provide a support structure.

In summation of the description above, this disclosure definitely can achieve the expected objectives and overcome the drawbacks of the prior art, and the disclosure complies with the patent application requirements, and thus is duly filed for patent application.

While this disclosure has been described by means of specific embodiments, numerous modifications and variations could be made thereto by those skilled in the art without departing from the scope and spirit of this disclosure set forth in the claims.

What is claimed is:

1. A vapor chamber structure, comprising:
a thin-sheet housing, with an interior substantially in a hollow form; and
a capillary layer, installed in the thin-sheet housing;
wherein the hollow interior of the thin-sheet housing is formed by an etching method, and a plurality of first support portions is formed therein, and a first material layer and a second material layer are coated onto two inner walls of the thin-sheet housing respectively, and the capillary layer is attached onto the first material layer closely.

2. The vapor chamber structure as claimed in claim 1, wherein the thin-sheet housing is made of a material selected from the group consisting of steel, titanium, and aluminum.

3. The vapor chamber structure as claimed in claim 1, wherein the thin-sheet housing is formed by covering a first plate and a second plate with each other.

4. The vapor chamber structure as claimed in claim 3, wherein the first plate comprises a first thin-sheet portion, and a first sealing edge continuously formed at the periphery of the first thin-sheet portion, and a first recessed space is enclosed and formed by the first thin-sheet portion and the first sealing edge.

5. The vapor chamber structure as claimed in claim 4, wherein the hollow form of the thin-sheet housing is formed by covering the second plate onto the first sealing edge to seal the first recessed space.

6. The vapor chamber structure as claimed in claim 4, wherein the second plate also comprises a second thin-sheet portion, and a second sealing edge continuously formed at the periphery of the second thin-sheet portion, and a second recessed space is enclosed and formed by the second thin-sheet portion and the second sealing edge.

7. The vapor chamber structure as claimed in claim 6, wherein the hollow form of the thin-sheet housing is formed by coupling the first and second sealing edges of the first and second plates with each other closely to seal the first and second recessed spaces.

8. The vapor chamber structure as claimed in claim 7, wherein the second recessed space has a plurality of second support portions formed therein.

9. The vapor chamber structure as claimed in claim 1, wherein the first material layer and the second material layer are formed by coating.

10. The vapor chamber structure as claimed in claim 9, wherein the coating is made of titanium.
